(19) United States
(12) Patent Application Publication
(10) Pub. No.: US 2026/0372103 A1
(43) Pub. Date: Nov. 19, 2026

(54) MOLDING STRUCTURE TO COMPENSATE FOR WARPAGE

(71) Applicant: Taiwan Semiconductor Manufacturing Co., Ltd., Hsinchu (TW)

(72) Inventors: Hsin-Yu Chen, Taipei City (TW); Yu-Hsiang Hu, Hsinchu (TW); Cheng-Chi Hsieh, Hsinchu (TW); Chien-Hsun Lee, Chu-tung Town (TW); Kathy Wei Yan, Hsinchu (TW)

(21) Appl. No.: 19/749,964

(22) Filed: Jul. 22, 2026

Related U.S. Application Data
(63) Continuation of application No. 18/958,735, filed on Nov. 25, 2024.

(51) Int. Cl. H10W 42/00; H10W 74/10; H10W 74/47; H10W 90/00

(52) U.S. Cl. CPC H10W 42/121; H10W 74/10; H10W 74/473; H10W 90/00

(57) ABSTRACT

In some embodiments, a device is described that includes die components on an upper surface of a redistribution layer interposer to provide a chip on interposer structure. A packaging substrate is present on the chip on interposer structure. A thermal ring is present on the packaging substrate, wherein the thermal ring is positioned about a perimeter of the chip on interposer structure. Molding material is deposited on the packaging substrate in a space between the thermal ring and the chip on interposer structure.

### CROSS-REFERENCE TO RELATED APPLICATIONS

This application is a continuation of U.S. Application No. 18/958,735, filed on Nov. 25, 2024, which application is hereby incorporated herein by reference.

### BACKGROUND

Since the invention of the integrated circuit (IC), the semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

In an attempt to further increase circuit density, three-dimensional (3D) ICs have been investigated. In a typical formation process of a 3D IC, two dies are bonded together and electrical connections are formed between each die and contact pads on a substrate. Interposer stacking is part of 3D IC technology, where a Through-Silicon-Via (TSV) embedded interposer is connected to a device silicon with a micro bump. 3D IC manufacturing process flows can be separated into two types. In a chip-on-chip-on-substrate (CoCoS) process flow, a silicon interposer chip is first attached onto a packaging substrate, and then a different device silicon chips is attached onto the interposer. In a chip-on-wafer-on-substrate (CoWoS) process flow, a device silicon chip is first attached onto a silicon interposer wafer, which is then diced. The resulting stacked silicon is then attached onto a substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a side cross-sectional view that illustrates the formation of a redistribution layer (RDL) on a carrier substrate, in accordance with some embodiments.

FIG. 2 is a side cross-sectional view that illustrates chip on interposer processing atop the redistribution layer (RDL), in accordance with some embodiments.

FIG. 3 is a side cross-sectional view that illustrates a solder bond process applied to the chip on interposer structure and transfer of the structure from a first carrier substrate to a second carrier substrate, in accordance with some embodiments.

FIG. 4 is a side cross-sectional view that illustrates flip chip bonding (FCB) of the chip on interposer structure from FIG. 3 onto a packaging substrate, in accordance with some embodiments.

FIG. 5 is a side cross-sectional view that illustrates mounting a thermal ring to the substrate, in accordance with some embodiments.

FIG. 6 is a side cross-sectional view illustrating dispensing molding onto the substrate between the ring and the chip on interposer structure, in accordance with some embodiments.

FIGS. 7 and 8 are side cross-sectional views illustrating a chip on wafer on substrate (CoWoS) device including molding that is present between the ring and the chip on interposer structure, in accordance with some embodiments of the present disclosure.

FIG. 9 is a top down view of a chip on wafer on substrate (CoWoS) device including molding that is present between the ring and the chip on interposer structure around a perimeter of the chip on interposer structure, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a molding material is applied to an upper surface of the substrate between the chip on interposer structure and the ring structure around a perimeter of the chip on interposer structure, wherein the molding material has a coefficient of thermal (CTE) that offsets the warpage of the substrate. For greater than two dimension packages, e.g., 2.5 dimension (2.5D) and 3 dimension (3D) packages, such as those used in artificial intelligence (AI) applications and high performance computing (HPC), to achieve greater device integration, larger interposers and substrates are being employed. However, as the size of the interposer and substrate structures increase, the potential for package warpage also increases. As will be described in further detail below, the methods and structures described herein position a molding material on the face of the packaging substrate that the chip on interposer structure is bonded to. The chip on interposer structure can include system on chip (SOC) structures and memory structures bonded to an interposer substrate. The molding material has a coefficient of thermal expansion (CTE) that counteracts warpage of the packing substrate and/or the interposer substrate. In some embodiments, the molding material is positioned between the chip on interposer structure and a thermal ring (also referred to as a ring structure) that is present around a perimeter of the chip on interposer structure.

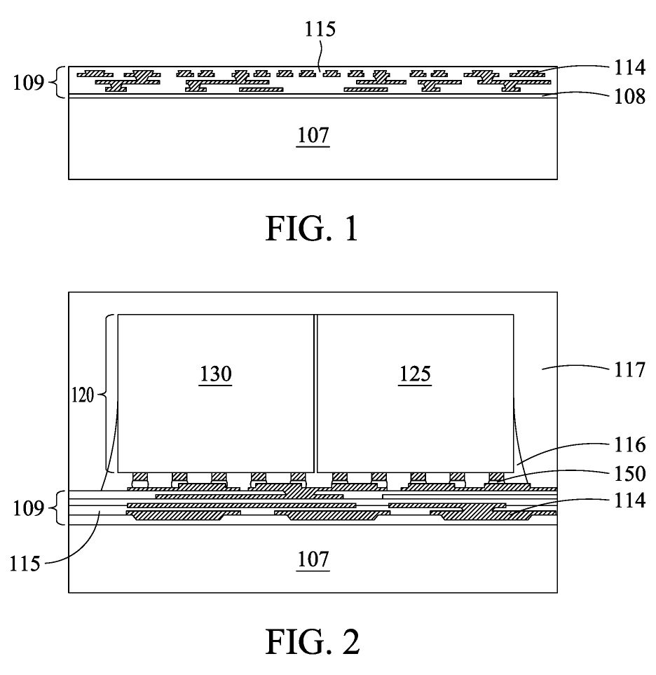

FIG. 1 is a side cross sectional view of a redistribution layer (RDL) interposer 109 that has been formed ont0 a first carrier substrate 107. The redistribution layer (RDL) interposer 109 includes one or more metal interconnect lines 114 that electrically connects later bonded top die components 120, e.g., the later connected package components 125, and/0r memory components 130, to the later bonded packaging substrate 137 for the purposes of signal and/or power routings. The one or more metal interconnect lines 114 of the redistribution layer (RDL) interposer 109 provide the electrical connections, allowing bond pads on the subsequently formed chips, e.g., packaging components 125 and/or memory components 130, to connect to leads or balls connecting the redistribution layer (RDL) interposer 109 to the packaging substrate 137. The bond pads for the top die components 120 may be bonded on interconnect vias to the one or more metal interconnect lines 114. The metal interconnect lines 114 may be present in one or more layers of insulating material. In some embodiments, the one or more layers of insulating material in the redistribution layer (RDL) interposer 109 may have an organic composition. For example, the insulating material in the redistribution layer (RDL) interposer 109 may be a polymeric composition. In some examples, the insulating material in the redistribution layer (RDL) interposer 109 may be an epoxy material. For example, the insulating material of the redistribution layer (RDL) interposer 109 may be an epoxy resin providing the matrix for the composite material, the composite material further including an amine based compound hardener, filler materials including silica and/or alumina, flexabilizers, and/or curing agents. In other embodiments, the insulating material of the redistribution layer (RDL) interposer 109 can be a silicon containing inorganic material. In some embodiments, the insulating material in the redistribution layer (RDL) interposer 109 may have a dielectric constant of less than 3.5. For example, the insulating material in the redistribution layer (RDL) interposer 109 may have a dielectric constant that is equal to 3.3.

The redistribution layer (RDL) interposer 109 may be formed using deposition processes, such as spin on deposition for forming the insulating materials, e.g., polymeric insulating materials. Openings and trenches for the metal lines and/or traces can be formed using photolithography and etch processes. Further, the metal material, such as copper and/or aluminum, for the metal lines and/or traces may be formed using deposition processes, such as sputtering, and/or plating. In some embodiments, the upper surface of the redistribution layer (RDL) interposer 109 may be planarized using a planarization process, such as chemical mechanical planarization (CMP).

FIG. 1 illustrates that the redistribution layer (RDL) interposer 109 may be formed on a supporting first carrier substrate 107 through a bonding layer 108. The first carrier substrate 107 may be composed of any rigid material, e.g., metal, glass and/or semiconductor material (e.g., silicon (Si). In some embodiments, the bonding layer 108 may be a release film, which may be a Light-to-Heat Conversion (LTHC) layer.

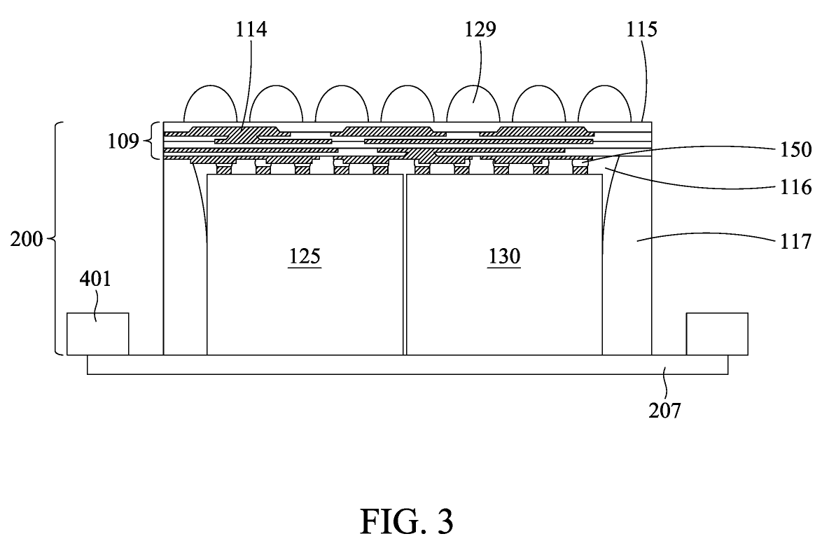

FIG. 2 illustrates chip on interposer processing atop the redistribution layer (RDL) interposer 109. In some embodiments, the chip on interposer processing may provide a Chip-on-Wafer-on-Substrate (CoWoS) substrate architecture including the redistribution layer (RDL) interposer 109. In one embodiment, the CoWoS substrate architecture may be CoWoS-R or CoWoS-L substrate architecture. CoWoS-R is a type of packaging that can employ Integrated Fan Out (InFO) wafer level packaging featuring at least one redistribution layer (RDL) with an organic insulating material and interconnect layers of a metal, such as copper. CoWoS-L include local silicon interconnect (LSI) chips for die-to-die interconnect and redistribution layers (RDLs) for power and signal deliver. In the embodiment depicted in FIG. 2, the redistribution layer (RDL) interposer 109 is composed of a polymer material, such as an epoxy.

In some embodiments, top die components 120 are bonded to the upper surface of the redistribution layer (RDL) interposer 109. The top die components 120 can include package components 125 and/or memory components 130. For example, the package components 125 may include a device die, a package with a device die(s) packaged therein, a System-on-Chip (SoC) or System-on-Integrated Circuit (SoIC) die including a plurality of integrated circuits (or device dies) integrated as a system, or the like. The device dies in package components 125 may be or may comprise logic dies, memory dies, input-output dies, Integrated Passive Devices (IPDs), or the like, or combinations thereof. For example, the logic device dies in package components may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 125 may include Static Random-Access Memory (SRAM) dies, Dynamic Random-Access Memory (DRAM) dies, or the like. The device dies in package components 125 may include semiconductor substrates and interconnect structures.

In some embodiments, the memory components 130 may include a memory stack, such as a High Bandwidth Memory (HBM) stack. In some other embodiments, the memory components 130 may include memory dies forming a die stack, and an encapsulate (such as a molding compound) encapsulating the memory dies therein.

In some embodiments, the top die components 120, e.g., the package components 125 and the memory components 130, may be bonded to the underlying redistribution layer (RDL) interposer 109, for example, through bonds 150. In accordance with some embodiments, the bonding is through a Chip-on-Wafer (CoW) bonding process, wherein the package components 125 and the memory components 130, which are discrete chips/packages, are bonded to the redistribution layer (RDL) interposer 109.

FIG. 2 illustrates bonding of the top die components 120, e.g., the package components 125, and the memory components 130, to the redistribution layer (RDL) interposer 109. The top die components 120 may be bonded to the contacts on the redistribution layer (RDL) interposer 109 using a solder bonding/flip chip type process. The bonds 150 provide for connection between the contacts pads of the one or more metal interconnect lines 114 and the contact pads of the top die components 120. In some embodiments, the solder bonding method may include micro-bumps, which can have a bump size of 25 microns or less. In some embodiments, the micro-bumps may also be composed of lead free materials, such as SnAg, SnCu, SnAgCu. In some other cases, the micro-bumps may be PbAg. The bonds 150 may be formed using indirect bonding, mass reflow, thermal compression bonding, direct bonding, Cu-to-Cu diffusion bonding, insert bump bonding and combinations thereof. It is noted that the above micro-bump methods are provided for illustrative purposes only. Other examples of solder application methods can include printing of solder paste, engraved mask stump, photosensitive organic mask and squeegee, electroplating of solder, evaporation, needle dispensing, solder paste printing, plated solder bumps, plated copper pillars with micro-bumps and combinations thereof.

After the application of solder to the contacts for the top die components 120, the solder may then be contacted to the contacts on the contact pads of the one or more metal interconnect lines 114 under elevated temperature and pressure to effectuate bonding. Following bonding, an underfill 116 may be applied. The underfill 116 may be a thermoset epoxy or polymer that's applied to the bonds 150 to protect them and strengthen solder joints.

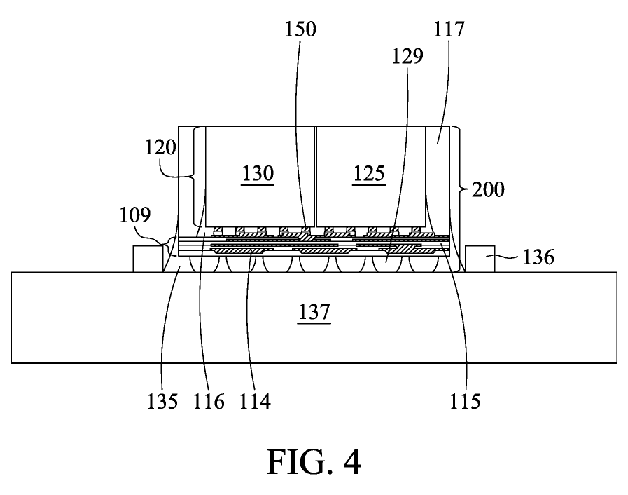

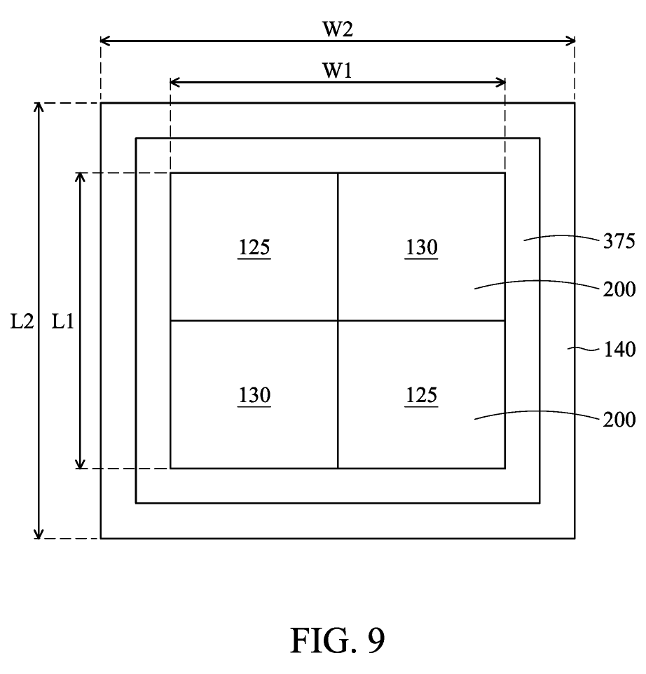

In some embodiments, the underfill 116 can be applied after the solder bump has gone through a reflow oven and can be dispensed using an automated syringe. The underfill 116 can then be applied, in which the underfill 116 flows underneath the top die components 120, e.g., the package components 125, and the memory components 130, using capillary action. In some embodiments, after application, the underfill 116 is cured by being heated. In some embodiments, the structure including the top die components 120 and the redistribution layer (RDL) interposer 109 may be referred to as a chip on interposer structure 200 (as depicted in FIG. 3). It is noted that the present disclosure is not limited to a chip on interposer structure 200 including a single packaging component 125 and a single memory component 130, as depicted in FIG. 3. For example, the chip on interposer structure 200 may include a plurality of packaging components 125 and a plurality of memory components 130. In some embodiments, when viewed from a top to down perspective, each of the width W1 and length L1 dimensions of the chip on interposer structure 200 may range from 60 mm to 70 mm, as depicted in FIG. 9. For example, the width W1 of the chip on interposer structure 200 may be equal to 66 mm, and the length L1 of the chip on interposer structure 200 may be equal to 68 mm.

Referring to FIG. 2, following the formation of the underfill 116, the structure may be encapsulated in an encapsulant 117, e.g., over molding. For example, the structure including at least the top die components 120, e.g., packaging components 125 and/or memory components, bonded to the redistribution layer (RDL) interposer 109, may be positioned within an mold, and a molding material may be injected into the mold to encapsulate the top die components 120 to the redistribution layer (RDL) interposer 109. The molding material for the encapsulant 117 may be an epoxy material. For example, the epoxy material for the encapsulant may include an epoxy for the structural matrix of the compound, a phenolic hardener, a fused silica filler, a coupling agent, a curing promotor and a release agent. In some embodiments, the aforementioned materials for the encapsulant may work together to protect the top die components 120, e.g., packaging components 125 and/or memory components 130, from environmental factors like moisture, heat, and physical stress, while also maintaining electrical insulation and structural integrity.

Referring to FIG. 3, following hardening of the molding material (also referred to as encapsulant 117), the hardened structure may be planarized, e.g., the molding material may be planarized using chemical mechanical planarization to expose an upper surface of the top die components 120. Still referring to FIG. 3, the exposed planarized upper surface of the top die components 120 may then be attached to a tape structure 207. For example, the planarized upper surface of the top die components 120 may be attached to the tape structure 207, in which the tape structure 207 also includes a ring structure 401. The ring structure 401 may be a metal ring intended to provide support and stability for the structure during and after the debonding process. In some embodiments, the tap structure 207 may be, e.g., a ultraviolet tape, although any other suitable adhesive or attachment may be used. In some embodiments, after the tape structure 207 is attached to the top die components 120, e.g., the package components 125, and the memory components 130, the first carrier substrate 107 may be removed. For example, the first carrier substrate 107 may be de-bonded, for example, by projecting a laser beam on the release film, thus decomposing the release film. After removing the first carrier substrate 107, the backside surface of the redistribution layer (RDL) interposer 109 is exposed.

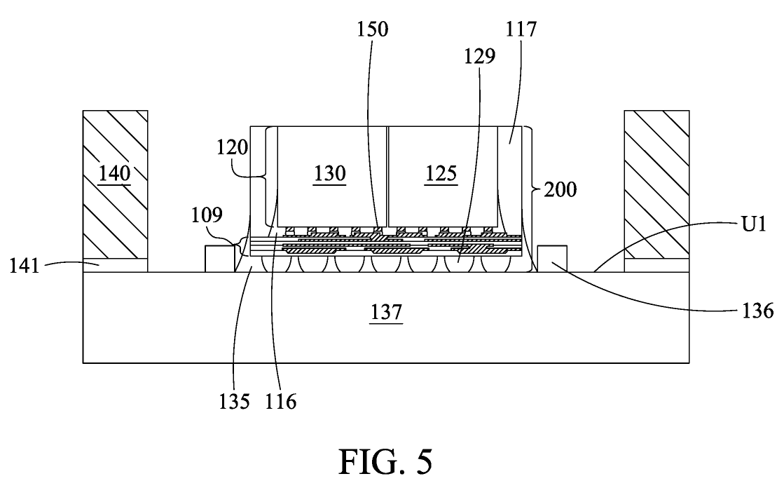

FIG. 3 illustrates one embodiment of a solder bond process applied to the chip on interposer structure 200. In some embodiments, solder bumps 129 are formed on the contacts to the one or more metal interconnect lines 114 of the redistribution layer (RDL) interposer 109. In some embodiments, the solder bumps 129 may be C4 bumps. C4 (collapse chip connection) bumps, can be used to bond the chip on interposer structure 200 to the packaging substrate 137, as depicted in FIG. 4. The term "solder", as used herein, refers to any metal or metallic compound or alloy that is melted and then allowed to cool in order to join two or more metallic surfaces together. Generally speaking, solders have melting temperatures in the range of 150°C to 250°C. Solder bumps may be small spheres of solder (solder balls) that are bonded to contact areas, interconnect lines or pads of semiconductor devices. In some embodiments, the solder bumps can be made from lead-free solder mixtures or lead tin solder.

In some embodiments, the solder bump process for forming the solder bonds can include an in-situ sputter clean to remove oxides or photoresist prior to metal deposition on the contacts to the one or more metal interconnect lines 114. The cleaning can also serve to roughen the surface of the contacts (also referred to as bond pad) in order to promote better adhesion of the under ball metallization (UBM). A metal mask can be used to pattern the structure for UBM and bump deposition. In one embodiments, a sequential evaporation of a chromium layer, a phased chromium/copper layer, a copper layer and an Au layer are deposited to form a thin film under ball metallurgy (UBM) on the contacts to the one or more metal interconnect lines 114. In one example, lead-tin solder is then evaporated on top of the UBM to form a thick layer. The height of the bump is determined by the volume of the evaporated material that is deposited. This is also a function of the distance between the metal mask and the wafer, as well as the size of the mask opening. The deposited solder is conical in shape, due to the way that the solder is formed in the openings of the solder mask. The solder can be reflowed to form a sphere.

FIG. 4 illustrates flip chip bonding (FCB) of the chip on interposer structure 200 from FIG. 3 onto a packaging substrate 137. In some embodiments, the packaging substrate 137 may be a printed circuit board (PCB). A printed circuit board (PCB) is an electronic assembly that uses copper conductors to create electrical connections between components. In some embodiments, the PCB employed for the packaging substrate 137 can be built from alternating layers of conductive copper with layers of electrically insulating material. In some embodiments, the packaging substrate 137 may be a semiconductor material substrate, such as a type IV or type III-V semiconductor substrate. In one example, the packaging substrate 137 may be composed of a silicon containing material, e.g., a silicon (Si) substrate, or a germanium containing material, e.g., a silicon germanium (SiGe) substrate.

After the formation of the solder bumps 129, the structure, e.g., chip on interposer structure 200, is flipped and the solder bumps 129 are aligned with contact pads (also referred to as bond pads) to the metal interconnect lines of the packaging substrate 137. In some embodiments, the accuracy of alignment may be of the order of a few microns for reliable function. Once a structure, e.g., chip on interposer structure 200, is aligned and flipped on the packaging substrate 137, the solder bumps 129 are reflowed to spread the conductive material evenly across the bond pads of the packaging substrate 137. This improves the wettability of solder and reduces the gap or standoff between the chip on interposer structure 200 and the packaging substrate 137. Following reflow, an underfill 135 is deposited at the edge of the assembly of the chip on interposer structure 200 and the packaging substrate 137. The underfill 135 may also be referred to as a chip on wafer (COW) molding. The underfill 135 is deposited on the edges of the chip on interposer structure 200, it flows across the gap between the chip on interposer structure 200 and the packaging substrate 137 by capillary action filling the space between the solder bumps 129. The underfill 135 depicted in FIG. 4 that is applied between the chip on interposer structure 200 and the packaging substrate 137 is similar to the underfill 116 that is positioned between the top die components 120 and the redistribution layer (RDL) interposer 109 that is illustrated in FIG. 3. Therefore, the description of the underfill 116 described above with reference to FIG. 3 is suitable for describing the underfill 135 that is present between the chip on interposer structure 200 and the packaging substrate 137. In some embodiments, to control the outward flow of the underfill 135, an edge dam 136 may be positioned at the edge of the chip on interposer structure 200. The final step in the flip chip process is to cure the underfill.

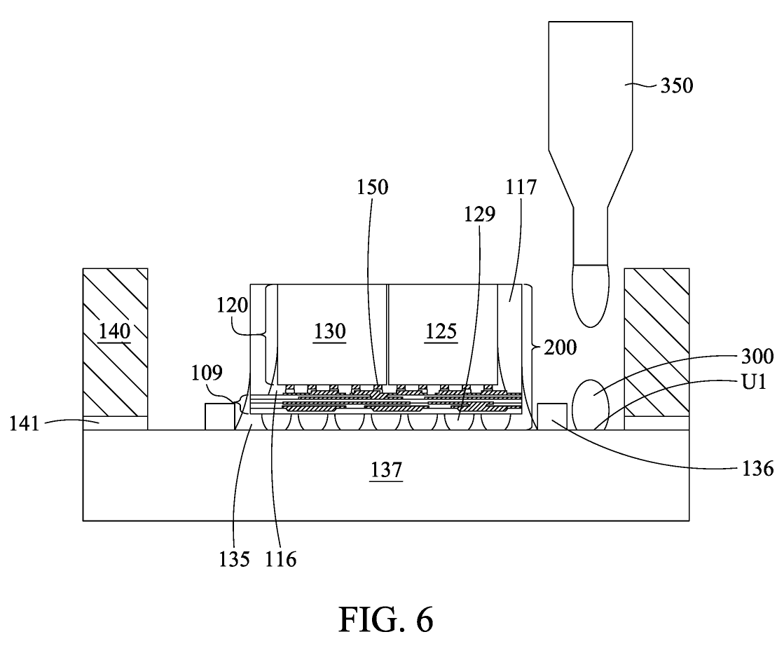

FIG. 5 illustrates bonding a ring structure 140 (also referred to as thermal ring) to the packaging substrate 137. The ring structure 140 may be provided for thermal cooling of the device. The ring structure 140 may be composed of a metal selected for heat dissipation performance, such as copper. However, any material that can dissipate heat generated in the package of the chip on interposer structure 200 and the packaging substrate 137 may be employed. The ring structure 140 is positioned on the face of the packaging substrate 137 that the chip on interposer structure 200 is bonded to. The ring structure 140 is position around a perimeter of the chip on interposer structure 200. In some embodiments, when viewed from a top to down perspective, each of the width W2 and length L2 dimensions of the ring structure 140 may range from 90 mm to 100 mm, as depicted in FIG. 9. For example, the width W2 of the ring structure 140 may be equal to 97.3 mm, and the length L2 of the ring structure 140 may be equal to 95 mm. In some embodiments, an exposed upper surface U1 of the packaging substrate 137 is present between the inner sidewall of the ring structure 140, and the edge of the chip on interposer structure 200.

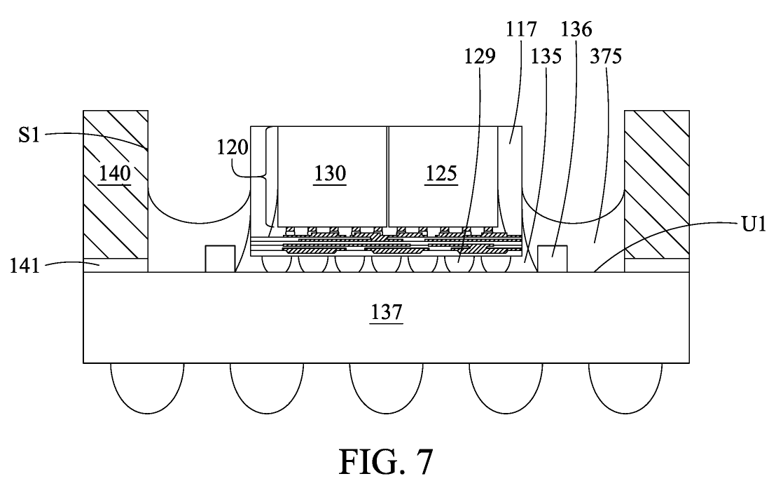

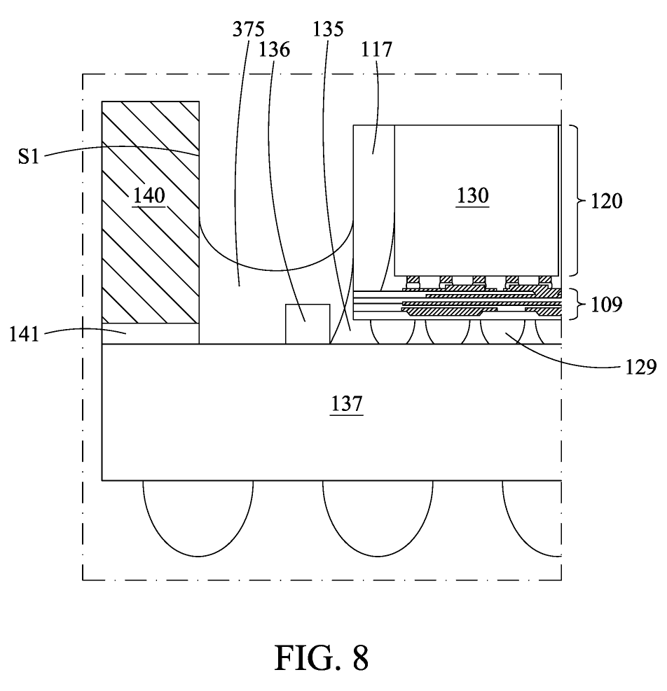

FIG. 6 illustrates dispensing molding liquid 300 onto the packaging substrate 137 between the ring structure 140 and the chip on interposer structure 200. The molding liquid 300 hardens to provide a molding material 375 filling a space between the ring structure 140 and the chip on interposer structure, as illustrated in FIG. 7. In some embodiments, molding material 375 is applied to an upper surface U1 of the packaging substrate 137 between the chip on interposer structure 200 and the ring structure 140 around a perimeter of the chip on interposer structure, wherein the molding material has a coefficient of thermal (CTE) that offsets the warpage of the substrate. The molding material 375 may be referred to as an on substrate molding material. For 2.5 dimension (2.5D) and (3D) packages employing larger sized substrates to increase device integration, the potential for package warpage can be great. The molding material 375 has a coefficient of thermal expansion (CTE) that counteracts warpage of the packaging substrate 137 and/or the redistribution layer (RDL) interposer 109. In some embodiments, the molding material 375 can have a coefficient of thermal expansion ranging from 10˚C/ppm to 40˚C/ppm. In some embodiments, the molding material 375 has a composition that includes an epoxy base material with a silicon oxide fill.

In some embodiments, the molding material 375 may be composed of an epoxy resin, a phenolic hardener, a fused silica filler, a coupling agent, and a curing promotor. In some embodiments, the epoxy resin in the primary component of the molding material, and can provide the structural matrix for the compound. In some embodiments, the phenolic hardener can facilitate curing of the epoxy resin, which facilitates making the molding material 375 hard and durable. The fused silica filler, e.g., silicon oxide filler, is added to adjust the thermal and mechanical properties of the compound. In some embodiments, the coupling agent can enhance adhesion between the resin and the filler. The curing promotor can accelerate the curing process.

An epoxy resin is a polymer containing generally two or more epoxide groups per molecule. In some embodiments, the epoxy resin component of the molding material 375 can include bisphenol epoxy resins, such as bisphenol A epoxy resins, bisphenol F epoxy resins, bisphenol S epoxy resins. In some other examples, the epoxy resin can include biphenyl epoxy resins, such as biphenyl epoxy resins, tetramethylbiphenyl epoxy resins, and the like. In some further examples, the epoxy resin can include novolac epoxy resins, such as phenol novolac epoxy resins, cresol novolac epoxy resins, bisphenol A novolac epoxy resins, epoxy compounds of condensates of phenols and phenolic hydroxyl group-containing aromatic aldehyde, biphenyl novolac epoxy resins, and the like.

In yet further examples, the epoxy resin can include triphenylmethane epoxy resins; tetraphenylethane epoxy resins; dicyclopentadiene phenol addition reaction-type epoxy resins; phenolaralkyl epoxy resins; epoxy resins each having a naphthalene skeleton in its molecular structure, such as naphthol novolac epoxy resins, naphtholaralkyl epoxy resins, and the like; brominated bisphenol epoxy resins, alicyclic epoxy resins, and glycidyl ether epoxy resins.

The aforementioned epoxy resins may be used alone or as a mixture of two or more. It is further noted that the above compositions are provided for illustrative purposes only, and are not intended to limit the present disclosure to solely those described above.

The amount of the epoxy resin in the molding material 375 can range from 5 wt. % to 15 wt. % based on the total weight of the epoxy molding compound. In another example, the amount of the epoxy resin in the molding material 375 can range 9 wt. % to 10 wt. % based on the total weight of the epoxy molding compound.

A phenolic resin is a polymer containing two or more hydroxyl groups per molecule. In some embodiments, the phenolic resin that can be used as the curing agent in the molding material 375 can include phenolic novolac resin (PN), cresol novolac resin, phenol aralkyl novolac resin, multi-aromatic novolac resin, multi-functional novolac resin, and mixtures thereof. In some embodiments, the amount of the phenolic resin in the molding material 375 compound ranges from 5 wt. % to 15 wt. % based on the total weight of the epoxy molding compound. In one example, the amount of the phenolic resin in the molding material 375 compound ranges from 7 wt. % to 11 wt. %.

The filler for the molding material 375 may include a wide range of fillers, which can improve certain properties of the molding material 375, such as abrasion resistance, moisture resistance, thermal conductivity or electrical properties. In some embodiments, the filler for the molding material 375 may include crystalline silica, fused silica, spherical silica, titanium oxide, aluminum hydroxide, magnesium hydroxide, zirconium dioxide, calcium carbonate, calcium silicate, talc, clay, carbon fiber, glass fiber and combinations thereof. In some embodiments, the amount of filler in the epoxy molding material can range from 65 wt. % to 80 wt.%.

The catalyst of the molding material 375 can catalyze or accelerate the curing reaction between the epoxy resin and the phenolic resin. In some examples, the catalyst of the molding material 375 can include one of amine compounds, organic phosphorus compounds, tetraphenyl phosphine compound and imidazole type compounds. In one example, the catalyst in the molding material 375 may range from 0.2 wt. % to 0.5 wt. % based on the total weight of the epoxy molding compound.

It is noted that the above compositions are provided for illustrative purposes only, and is not intended to limit the present disclosure. Other compositions can be equally suitable for the molding material 375 so long as the coefficient of thermal expansion for the molding material 375 may range from 10˚C/ppm to 40˚C/ppm.

As illustrated in FIG. 6, the molding material 375 may be deposited as a molding liquid 300 from a syringe 350, e.g., an automated syringe. In some embodiments, the molding liquid 300 may be deposited on the exposed upper surface U1 of the packaging substrate 137 that is present between the inner sidewall of the ring structure 140, and the edge of the chip on interposer structure 200. The molding liquid 300 may be deposited to fill the space between the ring structure 140 and the chip on interposer structure 200. In some embodiments, the molding liquid 300 may be cured for hardening. In some embodiments, when the molding liquid 300 provides an molding material 375 that is epoxy based, the liquid molding material may be cured with an anneal at a temperature ranging from 150˚C to 180˚C.

FIGS. 7 and 8 illustrate forming solder bumps on the opposite side of the packaging substrate 137 (e.g., printed circuit board (PCB) substrate) that the chip on interposer structure 200 is deposited on. The solder bumps may be configured in a ball grid array (BGA). FIG. 8 illustrates a more detailed view of aspects of the structure of FIG. 7, according to some embodiments.

Referring to FIGS. 7 and 8, the molding liquid 300 may be dispensed and cured to provide that the molding material 375 is present on the upper surface U1 of the packaging substrate 137 that the chip on interposer structure 200 is bonded to, and to provide that the molding material 375 extends to a height, e.g., thickness, so that the molding material 375 is in direct contact with the encapsulant 117 that is overmolded to encapsulate at least the sidewalls of the top die components 120. In some embodiments, the molding liquid 300 may be dispensed and cured to provide that the molding material 375 is present on the upper surface U1 of the packaging substrate 137, and to provide that the molding material 375 directly contacts the underfill 135 that is positioned at the edge of the assembly of the chip on interposer structure 200 and the packaging substrate 137. In some embodiments, the molding liquid 300 may be dispensed and cured to provide that the molding material 375 is present on the upper surface U1 of the packaging substrate 137, and to provide that the molding material 375 has a height, e.g., thickness that covers the edge dam 136 at the edge of the assembly of the chip on interposer structure 200 and the packaging substrate 137.

Still referring to FIGS. 7 and 8, the molding material 375 extends across the space separating the chip on interposer structure 200 and the ring structure 140 in direct contact with the upper surface U1 of the packaging substrate 137 into direct contact with the inside sidewall S1 of the ring structure 140. The upper surface of the molding material 375 has a concave curvature with the apex of the curvature being closest to the packaging substrate 137. The molding material 375 extends across the entirety of the space between the chip on interposer structure 200 and the ring structure 140.

FIG. 9 is a top down view illustrating how the molding material 375 is present around a perimeter of the chip on interposer structure 200 in the space between the chip on interposer structure 200 and the ring structure 140. In some embodiments, the molding material 375 is continuously present around the perimeter of the chip on interposer structure without breaks. However, in other embodiments the molding material 375 is present around only a portion of the perimeter of the chip on interposer structure 200.

In some embodiments, the device depicted in FIGS. 7 and 9 may include at least one of packaging components 125 and memory components 130 on an upper surface U1 of a redistribution layer (RDL) interposer 109 to provide a chip on interposer structure 200. The packaging substrate 137 is on an opposing side of the chip on interposer structure than the packaging components 125 and the memory components 130. A thermal ring (also referred to as ring structure 140) is also present on the packaging substrate 137, wherein the thermal ring (also referred to as ring structure 140) is positioned about a perimeter of the chip on interposer structure 200.

The molding material 375 is on the packaging substrate 137 filling a space between the thermal ring (also referred to as ring structure 140) and the chip on interposer structure 200.The amount of molding material 375 that is present on the upper surface U1 of the packaging substrate 137 is selected to counter act warpage that may occur in the packaging substrate 137 and/or the redistribution layer (RDL) interposer 109. For 2.5 dimension (2.5D) and (3D) packages employing larger sized substrates to increase device integration, the potential for package warpage can be great. The molding material has a coefficient of thermal expansion (CTE) that offsets the warpage of the packaging substrate 137 and/or the redistribution layer (RDL) interposer 109. In some embodiments, the molding material 375 can have a coefficient of thermal expansion (CTE) ranging from 10˚C/ppm to 40˚C/ppm.

In accordance with an embodiment, a method comprising: bonding die components to an upper surface of a redistribution layer interposer to provide a chip on interposer structure; bonding the chip on interposer structure onto a packaging substrate; bonding a thermal ring to the packaging substrate, wherein the thermal ring is positioned about a perimeter of the chip on interposer structure; and depositing a molding material on the packaging substrate in a space between the thermal ring and the chip on interposer structure. In an embodiment, the die components comprise a system on chip (SoC) component or a system on integrated circuit component (SoIC). In an embodiment, the molding material has a coefficient of thermal expansion ranging from 10˚C/ppm to 40˚C/ppm. In an embodiment, the molding material comprises an epoxy base material with a silicon oxide fill. In an embodiment, the die components comprise high bandwidth memory (HBM). In an embodiment, the molding material overlaps a chip on wafer (COW) molding that is present contacting the chip on interposer structure. In an embodiment, the molding material extends from an inner sidewall of the thermal ring to an outer sidewall of the chip on interposer structure. In an embodiment, the molding material has an upper surface with a concave curvature.

In accordance with another embodiment, a device comprising: die components on an upper surface of a redistribution layer interposer to provide a chip on interposer structure; a packaging substrate on a backside surface of the chip on interposer structure; a ring structure on the packaging substrate, wherein the ring structure is positioned about a perimeter of the chip on interposer structure; and molding material on the packaging substrate in a space between the ring structure and the chip on interposer structure. In some embodiments, an underfill material is between the die components and the upper surface of the redistribution layer interposer. In some embodiments, the molding material has a coefficient of thermal expansion ranging from 10˚C/ppm to 40˚C/ppm. In some embodiments, the molding material comprises an epoxy base material with a silicon oxide fill. In some embodiments, the die components comprise high bandwidth memory (HBM). In some embodiments, the molding material overlaps a chip on wafer (COW) molding that is present contacting the chip on interposer structure. In some embodiments, the molding extends from an inner sidewall of the thermal ring to an outer sidewall of the chip on interposer structure. In some embodiments, the molding material has an upper surface with a concave curvature.

In accordance with yet another embodiment, a device comprising: at least one of packaging components and memory components on an upper surface of a redistribution layer interposer to provide a chip on interposer structure; a packaging substrate on a backside surface of the chip on interposer structure; a thermal ring on the packaging substrate, wherein the thermal ring is positioned about a perimeter of the chip on interposer structure; and an epoxy base material with an inorganic filler on the packaging substrate within space between the thermal ring and the chip on interposer structure, wherein the epoxy base material with the inorganic filler has a coefficient of thermal expansion ranging from 10˚C/ppm to 40˚C/ppm. In some embodiments, the packaging components comprise a system on chip (SoC) component or a system on integrated circuit component (SoIC). In some embodiments, the memory components comprise high bandwidth memory (HBM). In some embodiments, the molding extends from an inner sidewall of the thermal ring to an outer sidewall of the chip on interposer structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a package component to a surface of a package substrate, wherein the package component comprises an integrated circuit die bonded to an interposer;
attaching a conductive ring to the surface of the package substrate, wherein the conductive ring surrounds the package component in a plan view; and
after attaching the conductive ring, forming a molding compound on the surface of the package substrate, wherein the molding compound is disposed between the conductive ring and the package component.

2. The method of claim 1, wherein the molding compound has a coefficient of thermal expansion ranging from 10˚C/ppm to 40˚C/ppm.

3. The method of claim 1, wherein forming the molding compound comprises:
dispensing a molding material in liquid form between the conductive ring and the package component; and
curing the molding material to provide the molding compound.

4. The method of claim 3, wherein after curing the molding material, a top surface of the molding compound is concave.

5. The method of claim 1, wherein the package component further comprises an encapsulant surrounding the integrated circuit die, wherein forming the molding compound comprises forming the molding compound to interface a sidewall of the encapsulant.

6. The method of claim 5, wherein the molding compound extends continuously from a sidewall of the conductive ring to the sidewall of the encapsulant.

7. The method of claim 1, further comprising dispensing an underfill between the package component and the package substrate, wherein forming the molding compound comprises forming the molding compound to interface a sidewall of the underfill.

8. The method of claim 7, wherein the underfill extends to a sidewall of a dam structure on the surface of the package substrate between the conductive ring and the package component, wherein forming the molding compound comprises forming the molding compound to cover the dam structure.

9. The method of claim 8, wherein a top surface of the molding compound is below a top surface of the package component.

10. A method comprising:
bonding one or more integrated circuit dies to a redistribution structure;
bonding the redistribution structure to a package substrate using a plurality of conductive connectors, wherein the plurality of conductive connectors are disposed on an opposing side of the redistribution structure as the one or more integrated circuit dies;
dispensing an underfill between the redistribution structure and the package substrate, wherein the underfill surrounds the plurality of conductive connectors;
attaching a heat dissipation feature to the package substrate;
dispensing a molding material between the heat dissipation feature and the underfill; and
curing the molding material, wherein after curing the molding material, the molding material covers a surface of the package substrate between the heat dissipation feature and the underfill.

11. The method of claim 10, wherein curing the molding material comprises an annealing process performed at a temperature in a range of 150˚C to 180˚C.

12. The method of claim 10, wherein the molding material comprises an epoxy resin and a filler material.

13. The method of claim 10, wherein the molding material has a coefficient of thermal expansion ranging from 10˚C/ppm to 40˚C/ppm.

14. The method of claim 10, wherein dispensing the underfill comprises containing a flow of the underfill using a dam on the surface of the package substrate.

15. The method of claim 14, wherein the molding material covers the dam.

16. A package structure comprising:
a package component comprising:
an integrated circuit die bonded to an interposer; and
an encapsulant over the interposer and surrounding the integrated circuit die;
a package substrate, wherein the package component is bonded to a top surface of the package substrate;
an underfill between the package substrate and the package component;
a heat dissipation feature attached to the top surface of the package substrate; and
a molding material on the top surface of the package substrate, wherein the molding material extends from a sidewall of the heat dissipation feature to a sidewall of the package component.

17. The package structure of claim 16, further comprising a dam on the top surface of the package substrate, wherein the underfill extends to a surface of the dam.

18. The package structure of claim 17, wherein the molding material covers the dam.

19. The package structure of claim 16, wherein a top surface of the underfill is concave.

20. The package structure of claim 16, wherein a top surface of the underfill is below a top surface of the heat dissipation feature and a top surface of the package component.
